(19) United States
(12) Patent Application Publication
(10) Pub. No.: US 2025/0060395 A1
(43) Pub. Date: Feb. 20, 2025

(54) PT PRIMARY VOLTAGE RECONSTRUCTION METHOD BASED ON INVERSE BLACK BOX MODEL AND INVERSE ELECTROMAGNETIC DUALITY MODEL

(71) Applicant: CHONGQING UNIVERSITY, Chongqing (CN)

(72) Inventors: Ming YANG, Chongqing (CN); Wenxia SIMA, Chongqing (CN); Binyang ZOU, Chongqing (CN); Tao YUAN, Chongqing (CN); Potao SUN, Chongqing (CN)

(73) Assignee: CHONGQING UNIVERSITY, Chongqing (CN)

(21) Appl. No.: 18/725,736

(22) PCT Filed: Nov. 15, 2022
(86) PCT No.: PCT/CN2022/131903

§ 371 Date: Jun. 28, 2024

(30) Foreign Application Priority Data
Dec. 31, 2021 (CN) 202111679244.3

(51) Int. Cl. G01R 19/25; G01R 19/10

(52) U.S. Cl. CPC G01R 19/2506; G01R 19/10; G01R 19/2513

(57) ABSTRACT

A method for reconstructing a primary voltage of a potential transformer (PT) based on an inverse black box model and an inverse electromagnetic duality model includes: collecting a secondary voltage signal of a power system by the PT, and dividing the secondary voltage signal into a low-frequency voltage component and a high-frequency voltage component; performing primary voltage reconstruction by applying the inverse black box model on the high-frequency voltage component, to obtain a primary-voltage high-frequency voltage component; performing primary voltage reconstruction by applying the inverse electromagnetic duality model on the low-frequency voltage component, to obtain a primary-voltage low-frequency voltage component; and integrating the primary-voltage high-frequency voltage component and the primary-voltage low-frequency voltage component, to obtain the primary voltage of the power system.

The present application claims the priority to Chinese patent application No. 202111679244.3, titled “PT PRIMARY VOLTAGE RECONSTRUCTION METHOD BASED ON INVERSE BLACK BOX MODEL AND INVERSE ELECTROMAGNETIC DUALITY MODEL”, filed on Dec. 31, 2021 with the China National Intellectual Property Administration, which is incorporated herein by reference in its entirety.

### FIELD

The present disclosure relates to the technical field of measurement, and more particularly, to a method, a device, and an apparatus for reconstructing a PT primary voltage based on an inverse black box and an inverse electromagnetic duality model.

### BACKGROUND

Voltage measurement and online monitoring are the keys to reliable operations of metering, fault diagnosis, and fault protection in power systems. A measured voltage waveform is one of the most informative and convincing waveforms in power systems. In a distribution network of 35 kV and below, the system voltage is generally measured by a potential transformer (PT). PT is an instrument transformer. A primary winding of the PT is directly connected to a power grid, and a secondary winding of the PT is connected to a metering instrument. There is no direct circuit connection between the primary winding of the PT and the secondary winding of the PT, but the magnetic field therebetween is used for coupling measurement. Therefore, electromagnetic isolation of the PT from a primary power system can be realized through magnetic coupling, being low in cost, accurate in measurement, safe and reliable. In the power systems, voltage-related fault diagnosis and fault protection rely on an accurate voltage signal output by the secondary side of the PT.

When the PT is operated within its nominal frequency (50/60 Hz) range and nominal voltage range, an accurate and stable measurement result can be provided, that is, the voltage transfer characteristic thereof is constant, there is almost no phase difference between the primary voltage and the secondary voltage, and the amplitude ratio between the primary voltage and the secondary voltage is equal to the turn ratio. However, when the primary side (primary winding) of the PT is excited by a high-frequency transient voltage or a low-frequency overvoltage, the signal at the secondary side of the PT may be distorted and thus is significantly different from an original primary side voltage, which means that transient voltage measurement results provided by the PT under these transient voltage excitations are rather inaccurate. Distorted secondary signals of the PT bring potential risks to voltage-based operations such as fault diagnosis and protection. At the same time, the distorted voltage signal may seriously mislead analysis and review after an accident.

### SUMMARY

A method, a device, and an apparatus for reconstructing a primary voltage of a potential transformer (PT) based on an inverse black box model and an inverse electromagnetic duality model are provided according to embodiments of the present disclosure, to solve the technical problem of inaccurate measurement data of the PT used for measuring a voltage in an existing power system due to distortion presented in the PT during a measurement process.

In order to realize the above object, technical solutions are provided according to embodiments of the present disclosure as follows.

A method for reconstructing a primary voltage of a potential transformer (PT) based on an inverse black box model and an inverse electromagnetic duality model includes:
collecting a secondary voltage signal of a power system by the PT, and dividing the secondary voltage signal into a low-frequency voltage component and a high-frequency voltage component;
performing primary voltage reconstruction by applying the inverse black box model on the high-frequency voltage component, to obtain a primary-voltage high-frequency voltage component;
performing primary voltage reconstruction by applying the inverse electromagnetic duality model on the low-frequency voltage component, to obtain a primary-voltage low-frequency voltage component; and
integrating the primary-voltage high-frequency voltage component and the primary-voltage low-frequency voltage component, to obtain the primary voltage of the power system.

Preferably, dividing the secondary voltage signal into a low-frequency voltage component and a high-frequency voltage component includes:
performing Fourier transform processing on the secondary voltage signal, to obtain a frequency domain of the secondary voltage signal;
dividing the frequency domain of the secondary voltage signal into a low-frequency domain of the secondary voltage signal and a high-frequency domain of the secondary voltage signal according to whether respective frequencies in the frequency domain of the secondary voltage signal are greater than a transition frequency; and
performing inverse Fourier transform on the low-frequency domain of the secondary voltage signal and the high-frequency domain of the secondary voltage signal, respectively, to obtain the low-frequency voltage component and the high-frequency voltage component.

Preferably, the performing primary voltage reconstruction by applying the inverse black box model on the high-frequency voltage component, to obtain a primary-voltage high-frequency voltage component includes:
inputting the high-frequency voltage component into the inverse black box model, to perform reconstructing conversion on the high-frequency voltage component by a transfer function of the inverse black box model, to obtain the primary-voltage high-frequency voltage component output by the inverse black box model,
where the transfer function is vₚₕ(s)=Hₘ⁻¹(s) vₛₕ(s), where vₛₕ(s) is an input variable of the inverse black box model, vₚₕ(s) is an output variable of the inverse black box model, and Hₘ⁻¹(s) is the transfer function of the inverse black box model.

Preferably, the performing reconstructing conversion on the high-frequency voltage component by a transfer function of the inverse black box model includes:
performing fitting transformation on the transfer function, to obtain a state equation of the transfer function;
converting the state equation by introducing a variable x and a center difference method, to obtain a discrete voltage reconstruction function;
performing iterative calculating on the discrete voltage reconstruction function, to obtain a reconstructed primary-voltage high-frequency voltage component;
where the discrete voltage reconstruction function is:

$$\frac{{x}_{k} - {x}_{k - 1}}{Δ t} = A \frac{{x}_{k} + {x}_{k - 1}}{2} + B \frac{{v}_{s h ( k )} + {v}_{s h ( k - 1 )}}{2}$$

$${v}_{p h ( k )} = C {x}_{k} + D {v}_{s h ( k )}$$

where x is a symbol of the introduced variable, k and k−1 are time points of the k-th and (k−1)-th of high-frequency voltage components, A is an N×N diagonal matrix of an extreme point of the transfer function, B is an N×1 array, Δt is a time interval between time points corresponding to the k-th high-frequency voltage component and the (k−1)-th high-frequency voltage component, C is an 1×N array of a zero point of the transfer function, and D is a constant term.

Preferably, the performing primary voltage reconstruction by applying the inverse electromagnetic duality model on the low-frequency voltage component, to obtain a primary-voltage low-frequency voltage component includes:
inputting the low-frequency voltage component into the inverse electromagnetic duality model, to perform reconstructing conversion on the low-frequency voltage component by a flux linkage conservation of the inverse electromagnetic duality model and a Kirchhoff's current and voltage law, to obtain the primary-voltage low-frequency voltage component output by the inverse electromagnetic duality model,
where the Kirchhoff' current and voltage law is:

$${v}_{p l} = n {v}_{m 1} + {R}_{s 1} {i}_{p l} ;$$

$${v}_{m 1} = {v}_{L s} + {v}_{m 2} ;$$

$${i}_{p l} = \frac{{i}_{m 1} + {i}_{L s}}{n} ;$$

where vₚₗ is the primary-voltage low-frequency voltage component, n is a turn ratio of the inverse electromagnetic duality model, vₘ₁ is a voltage of a first excitation branch in the inverse electromagnetic duality model, vₘ₂ is a voltage of a second excitation branch in the inverse electromagnetic duality model, v_{Ls} is a voltage across a leakage inductance in the inverse electromagnetic duality model, Rₛ₁ is a resistance of a primary winding in the inverse electromagnetic duality model, iₚₗ is a primary current of the inverse electromagnetic duality model, iₘ₁ is a current flowing through the first excitation branch in the inverse electromagnetic duality model, and i_{Ls} is a current flowing across the leakage inductance in the inverse electromagnetic duality model.

Preferably, the PT primary voltage reconstruction method based on inverse black box model and inverse electromagnetic duality model includes: adding the primary-voltage high-frequency voltage component and the primary-voltage low-frequency voltage component, to obtain the primary voltage of the power system.

A device for reconstructing a primary voltage of a potential transformer (PT) based on an inverse black box model and an inverse electromagnetic duality model is further provided according to the present disclosure, including a frequency component extraction module, a high-frequency back calculation module, a low-frequency back calculation module, and an integration module,
where the frequency component extraction module is configured to collect a secondary voltage signal of a power system by the PT, and divide the secondary voltage signal into a low-frequency voltage component and a high-frequency voltage component;
the high-frequency back calculation module is configured to perform primary voltage reconstruction by applying the inverse black box model on the high-frequency voltage component, to obtain a primary-voltage high-frequency voltage component;
the low-frequency back calculation module is configured to perform primary voltage reconstruction by applying the inverse electromagnetic duality model on the low-frequency voltage component, to obtain a primary-voltage low-frequency voltage component; and
the integration module is configured to integrate the primary-voltage high-frequency voltage component and the primary-voltage low-frequency voltage component, to obtain the primary voltage of the power system.

Preferably, the high-frequency back calculation module is further configured to: input the high-frequency voltage component into the inverse black box model, to perform reconstructing conversion on the high-frequency voltage component by a transfer function of the inverse black box model, to obtain the primary-voltage high-frequency voltage component output by the inverse black box model,
where the transfer function is vₚₕ(s)=Hₘ⁻¹(s) vₛₕ(s), where vₛₕ(s) is an input variable of the inverse black box model, vₚₕ(s) is an output variable of the inverse black box model, and Hₘ⁻¹(s) is the transfer function of the inverse black box model;
where the high-frequency back calculation module includes a conversion sub-module and a calculation sub-module,
where the conversion sub-module is configured to perform fitting transformation on the transfer function, to obtain a state equation of the transfer function; and convert the state equation by introducing a variable x and a center difference method, to obtain a discrete voltage reconstruction function, and
the calculation sub-module is configured to perform iterative calculating on the discrete voltage reconstruction function, to obtain a reconstructed primary-voltage high-frequency voltage component,
where the discrete voltage reconstruction function is:

$$\begin{matrix}\frac{{x}_{k} - {x}_{k - 1}}{Δ t} = A \frac{{x}_{k} + {x}_{k - 1}}{2} + B \frac{{v}_{s h ( k )} + {v}_{s h ( k - 1 )}}{2} \\ {v}_{p h ( k )} = C {x}_{k} + D {v}_{s h ( k )}\end{matrix}$$

where x is a symbol of the introduced variable, k and k−1 are time points of the k-th and (k−1)-th of high-frequency voltage components, A is an N×N diagonal matrix of an extreme point of the transfer function, B is an N×1 array, Δt is a time interval between time points corresponding to the k-th high-frequency voltage component and the (k−1)-th high-frequency voltage component, C is an 1×N array of a zero point of the transfer function, and D is a constant term.

Preferably, the low-frequency back calculation module is further configured to: input the low-frequency voltage component into the inverse electromagnetic duality model, to perform reconstructing conversion on the low-frequency voltage component by a flux linkage conservation of the inverse electromagnetic duality model and a Kirchhoff's current and voltage law, to obtain the primary-voltage low-frequency voltage component output by the inverse electromagnetic duality model,
where the Kirchhoff's current and voltage law is:

$${v}_{p l} = n {v}_{m 1} + {R}_{s 1} {i}_{p l} ;$$

$${v}_{m 1} = {v}_{L s} + {v}_{m 2} ;$$

$${ι}_{p l} = \frac{}{n} ;$$

where vₚₗ is the primary-voltage low-frequency voltage component, n is a turn ratio of the inverse electromagnetic duality model, vₘ₁ is a voltage of a first excitation branch in the inverse electromagnetic duality model, vₘ₂ is a voltage of a second excitation branch in the inverse electromagnetic duality model, v_{Ls} is a voltage across a leakage inductance in the inverse electromagnetic duality model, Rₛ₁ is a resistance of a primary winding in the inverse electromagnetic duality model, iₚₗ is a primary current of the inverse electromagnetic duality model, iₘ₁ is a current flowing through the first excitation branch in the inverse electromagnetic duality model, and i_{Ls} is a current flowing across the leakage inductance in the inverse electromagnetic duality model.

An apparatus for reconstructing a primary voltage of a potential transformer (PT) based on an inverse black box model and an inverse electromagnetic duality model is further provided in the present disclosure, including a processor and a memory,
where the memory is configured to store program codes, and transmit the program codes to the processor; and
the processor is configured to execute instructions in the program codes to implement the method for reconstructing a primary voltage of a potential transformer (PT) based on an inverse black box model and an inverse electromagnetic duality model.

As can be seen from the above technical solutions, the embodiments of the present disclosure have the following advantages. A method, a device, and an apparatus for reconstructing a primary voltage of a potential transformer (PT) based on an inverse black box model and an inverse electromagnetic duality model are provided. The method includes: collecting a secondary voltage signal of a power system by the PT, and dividing the secondary voltage signal into a low-frequency voltage component and a high-frequency voltage component; performing primary voltage reconstruction by applying the inverse black box model on the high-frequency voltage component, to obtain a primary-voltage high-frequency voltage component; performing primary voltage reconstruction by applying the inverse electromagnetic duality model on the low-frequency voltage component, to obtain a primary-voltage low-frequency voltage component; and integrating the primary-voltage high-frequency voltage component and the primary-voltage low-frequency voltage component, to obtain the primary voltage of the power system. According to the method for reconstructing a primary voltage of a PT based on an inverse black box model and an inverse electromagnetic duality model, the high-frequency voltage component and the low-frequency voltage component obtained by dividing the secondary voltage signal collected by the PT are respectively processed by the inverse black box model and the inverse electromagnetic duality model, to obtain the primary-voltage high-frequency voltage component and the primary-voltage low-frequency voltage component, and then the primary-voltage high-frequency voltage component and the primary-voltage low-frequency voltage component are added to obtain a primary voltage, so that the obtained primary voltage is not affected by distortion in the PT acquisition process, and the data accuracy is high, thereby solving the technical problem of inaccurate measurement data of the PT used for measuring a voltage in an existing power system due to distortion presented in the PT during a measurement process.

### BRIEF DESCRIPTION OF THE DRAWINGS

In order to describe the embodiments of the present disclosure or the technical solutions in the existing technologies more clearly, accompanying drawings required for the description of the embodiments or the existing technologies will be made briefly below. Apparently, the accompanying drawings described below are merely some of the embodiments of the present disclosure, and those skilled in the art can obtain other drawings according to these drawings without any inventive effort.

FIG. 1 is a flow chart of steps of a method for reconstructing a primary voltage of a potential transformer (PT) based on an inverse black box model and an inverse electromagnetic duality model according to an embodiment of the present disclosure;

FIG. 2 is a flow chart showing signal dividing steps of a method for reconstructing a primary voltage of a potential transformer (PT) based on an inverse black box model and an inverse electromagnetic duality model according to an embodiment of the present disclosure;

FIG. 3 is a schematic diagram of an inverse electromagnetic duality model in a method for reconstructing a primary voltage of a potential transformer (PT) based on an inverse black box model and an inverse electromagnetic duality model according to an embodiment of the present disclosure;

FIG. 4 is a comparison diagram of a distorted signal and a reconstructed signal by a potential transformer (PT) based on an inverse black box model and an inverse electromagnetic duality model according to an embodiment of the present disclosure;

FIG. 5 is a comparison diagram of a distorted signal and a reconstructed signal by a potential transformer (PT) based on an inverse black box model and an inverse electromagnetic duality model according to another embodiment of the present disclosure; and

FIG. 6 is a block diagram of a device for reconstructing a primary voltage of a potential transformer (PT) based on an inverse black box model and an inverse electromagnetic duality model according to an embodiment of the present disclosure.

### DETAILED DESCRIPTION OF EMBODIMENTS

In order to make the objectives, technical solutions and advantages of the embodiments of the present disclosure clearer, technical solutions of embodiments of the present disclosure are described clearly and completely in conjunction with the drawings of the embodiments of the present disclosure. Apparently, the embodiments described below are only some embodiments, rather than all the embodiments of the present disclosure. Any other embodiments obtained by those skilled in the art based on the embodiments in the present disclosure without any creative effort shall fall within the protection scope of the present disclosure.

Terms of the present disclosure are explained as follows.

An electromagnetic potential transformer (PT) is a voltage measuring device realizing electromagnetic isolation through a transformer, and is also an instrument transformer. The basic principle of the PT is identical to that of the transformer.

On-line monitoring refers to continuous or timed monitoring of a condition of a monitored device while the monitored device is in operation, usually automatically.

A PT primary side refers to a primary winding (high-voltage winding), directly connected to the power grid, of the PT.

A PT primary voltage refers to a voltage across the primary winding of the PT.

A PT secondary side refers to a secondary winding (low-voltage winding), directly connected to a metering device or the like, of the PT.

A PT secondary signal refers to a voltage across the secondary winding of the PT and is also a measured signal.

A black box model refers to a port equivalent model, which has no physical significance, and can only realize port characteristics consistent with a modeled device. The black box model of the PT has a significant accuracy in the simulation of high-frequency characteristics, but has a large error in low-frequency characteristics due to some factors of measurement.

An electromagnetic duality model is a model derived based on an electromagnetic duality principle in which a magnetic circuit model of a device is represented as an electric circuit according to a duality relationship of electric quantity and magnetic quantity, and has physical significance. The electromagnetic duality model may have different fineness according to different applicable frequency ranges. However, the electromagnetic duality model requires a very complex model topology in the simulation of the high-frequency characteristics, and has a high requirement for parameter accuracy. Therefore, it is difficult to obtain all the parameters through test and measurement, and the detailed design parameters of the device are required. The electromagnetic duality model applied to middle and low-frequencies has a high accuracy.

An inverse model is opposite to a forward model. Taking the PT as an example, the input of the PT is the primary voltage, and the output is the secondary signal. A model of obtaining the secondary signal based on the primary voltage is a forward model. For the inverse model, the input thereof is the secondary signal, and the output is an actual primary voltage. That is, a model of obtaining the primary voltage based on the secondary signal is the inverse model.

A method, a device, and an apparatus for reconstructing a primary voltage of a potential transformer (PT) based on an inverse black box model and an inverse electromagnetic duality model are provided according to embodiments of the present disclosure, applied to a small-current grounding system of a power distribution network, and used to solve a technical problem of inaccurate measurement data of the PT used for measuring a voltage in an existing power system due to distortion presented in the PT during a measurement process.

### Embodiment 1

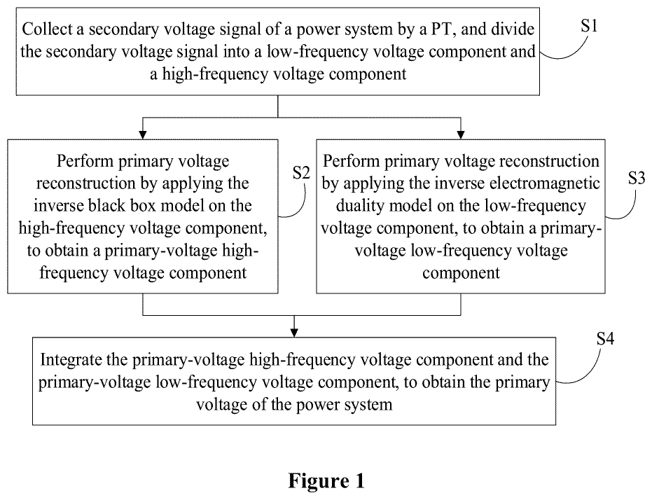

FIG. 1 is a flow chart of steps of a method for reconstructing a primary voltage of a potential transformer (PT) based on an inverse black box model and an inverse electromagnetic duality model according to an embodiment of the present disclosure.

As shown in FIG. 1, a method for reconstructing a primary voltage of a potential transformer (PT) based on an inverse black box model and an inverse electromagnetic duality model is provided according to an embodiment of the present disclosure, the method including steps S1 to S4.

In S1, a secondary voltage signal of a power system is collected by a PT, and is divided into a low-frequency voltage component and a high-frequency voltage component.

It should be noted that mainly in step S1, the secondary voltage signal of the power system collected by the PT is divided into the low-frequency voltage component and the high-frequency voltage component, so as to facilitate the processing of converting the secondary voltage signal into a primary voltage in subsequent steps.

In S2, primary voltage reconstruction is performed by applying the inverse black box model on the high-frequency voltage component, to obtain a primary-voltage high-frequency voltage component.

It should be noted that mainly in step S2, the high-frequency voltage component obtained according to step S1 is analyzed and processed by using the inverse black box model, to obtain the primary-voltage high-frequency voltage component. In the method for reconstructing a primary voltage of a PT based on an inverse black box model and an inverse electromagnetic duality model, reconstruction of the primary voltage signal is realized based on discrete secondary voltage signal data through the inverse black box model, so as to obtain the primary-voltage high-frequency voltage component conveniently, which has high stability.

In S3, primary voltage reconstruction is performed by applying the inverse electromagnetic duality model on the low-frequency voltage component, to obtain a primary-voltage low-frequency voltage component.

It should be noted that mainly in step S3, the low-frequency voltage component obtained according to step S1 is analyzed and processed by using the inverse electromagnetic duality model, to obtain the primary-voltage low-frequency voltage component. In the method for reconstructing a primary voltage of a PT based on an inverse black box model and an inverse electromagnetic duality model, the primary voltage reconstruction is realized based on the low-frequency component of the secondary voltage signal by considering deep saturation through the inverse electromagnetic duality model. Further, parameters of the inverse electromagnetic duality model can be obtained by a mature method without training with a large amount of measured data for modeling, so that the calculation is simplified.

In S4, the primary-voltage high-frequency voltage component and the primary-voltage low-frequency voltage component are integrated, to obtain the primary voltage of the power system.

It should be noted that mainly in step S4, the primary-voltage high-frequency voltage component obtained according to step S2 and the primary-voltage low-frequency voltage component obtained according to step S3 are integrated by adding together, to obtain the primary voltage of the power system. In the method for reconstructing a primary voltage of a PT based on an inverse black box model and an inverse electromagnetic duality model, the secondary voltage signal collected by the PT is processed to obtain the primary voltage, thereby avoiding the problem that the measurement data is inaccurate due to distortion in the PT measurement power system. The method for reconstructing a primary voltage of a PT based on an inverse black box model and an inverse electromagnetic duality model realizes the reconstruction of a high-frequency transient state of the PT primary side and the reconstruction of the low-frequency transient overvoltage of the PT primary side.

The method for reconstructing a primary voltage of a PT based on an inverse black box model and an inverse electromagnetic duality model provided in the present disclosure includes the following steps: collecting a secondary voltage signal of a power system by the PT, and dividing the secondary voltage signal into a low-frequency voltage component and a high-frequency voltage component; performing primary voltage reconstruction by applying the inverse black box model on the high-frequency voltage component, to obtain a primary-voltage high-frequency voltage component; performing primary voltage reconstruction by applying the inverse electromagnetic duality model on the low-frequency voltage component, to obtain a primary-voltage low-frequency voltage component; and integrating the primary-voltage high-frequency voltage component and the primary-voltage low-frequency voltage component, to obtain the primary voltage of the power system. According to the method for reconstructing a primary voltage of a PT based on an inverse black box model and an inverse electromagnetic duality model, the high-frequency voltage component and the low-frequency voltage component obtained by dividing the secondary voltage signal collected by the PT are respectively processed by the inverse black box model and the inverse electromagnetic duality model to respectively obtain the primary-voltage high-frequency voltage component and the primary-voltage low-frequency voltage component, and then the primary-voltage high-frequency voltage component and the primary-voltage low-frequency voltage component are added together, to obtain a primary voltage, so that the obtained primary voltage is not affected by the distortion in the PT acquisition process, and the data accuracy is high. The technical problem of inaccurate measurement data of the PT used for measuring a voltage in an existing power system due to distortion presented in the PT during a measurement process is solved.

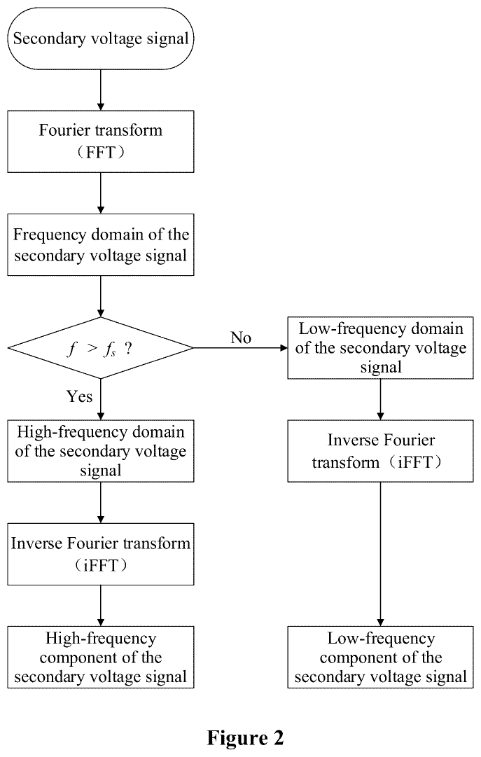

FIG. 2 is a flow chart showing signal dividing steps of a method for reconstructing a primary voltage of a potential transformer (PT) based on an inverse black box model and an inverse electromagnetic duality model according to an embodiment of the present disclosure.

As shown in FIG. 2, in an embodiment of the present disclosure, dividing the secondary voltage signal into a low-frequency voltage component and a high-frequency voltage component includes:
performing Fourier transform processing on the secondary voltage signal, to obtain a frequency domain of the secondary voltage signal;
dividing the frequency domain of the secondary voltage signal into a low-frequency domain of the secondary voltage signal and a high-frequency domain of the secondary voltage signal according to whether respective frequencies in the frequency domain of the secondary voltage signal are greater than a transition frequency; and
performing inverse Fourier transform on the low-frequency domain of the secondary voltage signal and the high-frequency domain of the secondary voltage signal, respectively, to obtain the low-frequency voltage component and the high-frequency voltage component.

It should be noted that it is mainly to divide the secondary voltage signal into a low-frequency voltage component and a high-frequency voltage component. Specifically, by Fourier transform (FFT), the secondary voltage signal is converted from a time domain signal into a frequency domain signal, and then selecting is performed by using the transition frequency fₛ. If a frequency in the frequency domain of the secondary voltage signal is higher than the transition frequency fₛ, this frequency belongs to the high-frequency domain of the secondary voltage signal; if a frequency in the frequency domain of the secondary voltage signal is lower than or equal to the transition frequency fₛ, this frequency belongs to the low-frequency domain of the secondary voltage signal. The high-frequency voltage component in the time domain corresponding to the secondary voltage signal can be obtained by performing inverse Fourier transform (iFFT) on components having frequencies greater than the transition frequency fₛ. Similarly, the low-frequency voltage component in the time domain corresponding to the secondary voltage signal can be obtained by performing iFFT on components having frequencies smaller than or equal to the transition frequency fₛ. The low-frequency voltage component and the high-frequency voltage component are distinguished by the back calculation transition frequency fₛ. The transition frequency fₛ depends on a measurement result of scattering parameters of PT voltage transfer characteristics and is typically much less than the first resonant point of the PT voltage transfer characteristic changing with a frequency. For example, the transition frequency fₛ is typically less than 0.1 times of a frequency at that frequency point. Thus, the transition frequency fₛ may be defined according to requirements, and is not limited herein.

In an embodiment of the present disclosure, the step of performing primary voltage reconstruction by applying the inverse black box model on the high-frequency voltage component, to obtain a primary-voltage high-frequency voltage component includes:
inputting the high-frequency voltage component into the inverse black box model, and performing reconstructing conversion on the high-frequency voltage component by a transfer function of the inverse black box model, to obtain the primary-voltage high-frequency voltage component output by the inverse black box model.

Here, the transfer function is vₚₕ(s)=Hₘ⁻¹(s) vₛₕ(s), where vₛₕ(s) is the input variable of the inverse black box model, vₚₕ(s) is the output variable of the inverse black box model, and Hₘ⁻¹(s) is the transfer function of the inverse black box model.

In an embodiment of the present disclosure, performing reconstructing conversion on the high-frequency voltage component by a transfer function of the inverse black box model includes:
performing fitting transformation on the transfer function, to obtain a state equation of the transfer function;
converting the state equation by introducing a variable x and a center difference method, to obtain a discrete voltage reconstruction function; and
performing iterative calculating on the discrete voltage reconstruction function, to obtain a reconstructed primary-voltage high-frequency voltage component.

Here, the discrete voltage reconstruction function is:

$$\begin{matrix}\frac{{x}_{k} - {x}_{k - 1}}{Δ t} = A \frac{{x}_{k} + {x}_{k - 1}}{2} + B \frac{{v}_{s h ( k )} + {v}_{s h ( k - 1 )}}{2} \\ {v}_{p h ( k )} = C {x}_{k} + D {v}_{s h ( k )}\end{matrix} ;$$

where x is a symbol of the introduced variable, k and k−1 are time points of the k-th and (k−1)-th of high-frequency voltage components, A is an N×N diagonal matrix of an extreme point of the transfer function, B is an N×1 array, Δt is a time interval between time points corresponding to the k-th high-frequency voltage component and the (k−1)-th high-frequency voltage component, C is an 1×N array of a zero point of the transfer function, and D is a constant term.

It should be noted that the inverse black box model is mainly used to reconstruct a primary-voltage high-frequency voltage component based on the high-frequency voltage component of the secondary signal. Specifically, the data obtained from the high-frequency voltage component by the inverse black box model is simplified by using a scattering matrix, to obtain the PT voltage transfer characteristics between the primary voltage and the secondary voltage signal, that is, Hₘ(s):

$${H}_{m} ( s ) = \frac{{v}_{s h} ( s )}{{v}_{p h} ( s )} = \frac{2 {S}_{12}}{( 1 + {S}_{11} ) ( 1 - {S}_{22} ) + {S}_{12} {S}_{21}} ;$$

where vₛₕ(s) is a secondary high-frequency and high-voltage component, vₚₕ(s) is a primary-voltage high-frequency voltage component, and S₁₁, S₁₂, S₂₁, and S₂₂ are matrix elements of the scattering matrix S. As a result, vₛₕ(s)=Hₘ(s)vₚₕ(s) can be obtained. Since the primary voltage is reconstructed by the inverse black box model based on the secondary voltage signal, this equation can be rewritten as vₚₕ(s)=Hₘ⁻¹(s) vₛₕ(s). It can be seen that Hₘ⁻¹(s) is the transfer function of the inverse black box model, and fitting can be performed on Hₘ⁻¹(s) by a vector matching method, to obtain Hᵢ(s) in the rational fractional form:

$${H}_{i} ( s ) \approx {\sum }_{k = 1}^{N} \frac{{r}_{k}}{s - {p}_{k}} + d + es ;$$

where, d is a constant term, e is a linear term coefficient, rₖ and pₖ are a zero point and an extreme point of the frequency domain response Hᵢ(s), and N is the order of fit. Hᵢ(s) in the rational fractional form is converted to the state equation of the transfer function: Hᵢ(s)=C(sI−A)⁻¹B+D+Es, where I is a standard unit matrix of N*N with the diagonal elements being all 1 and the remainder being 0; D and E correspond to d and e, respectively. In the scattering matrix, E is generally equal to 0. After obtaining the inverse voltage transfer function Hᵢ(s), a new variable x may be defined to introduce the high-frequency component vₚₕ of the primary voltage and the high-frequency voltage component vₛₕ of the secondary signal. x is defined as: x=(SI−A)⁻¹ Bvₛₕ, and \dot{x}=Ax+Bvₛₕ, vₚₕ=Cx+Dvₛₕ are obtained. Since the collected secondary voltage signal is a discrete signal rather than continuous data, but the state equation is suitable for continuous data, the state equation is converted by the central difference method so that it can be adapted to the discrete data, to obtain a discrete voltage reconstruction function for voltage reconstruction, that is:

$$\begin{matrix}\frac{{x}_{k} - {x}_{k - 1}}{Δ t} = A \frac{{x}_{k} + {x}_{k - 1}}{2} + B \frac{{v}_{s h ( k )} + {v}_{s h ( k - 1 )}}{2} \\ {v}_{p h ( k )} = C {x}_{k} + D {v}_{s h ( k )}\end{matrix} ;$$

The discrete voltage reconstruction function is simplified to obtain:

$${x}_{k} = a {x}_{k - 1} + λ B {v}_{s h ( k )} + μ B {v}_{s h ( k - 1 )} , {v}_{p h ( k )} = C {x}_{k} + D {v}_{s h ( k )} ,$$

where,

$$\begin{matrix}α = {( I - A \frac{Δ t}{2} )}^{- 1} ( I + A \frac{Δ t}{2} ) \\ λ = μ = {( I - A \frac{Δ t}{2} )}^{- 1} \frac{Δ t}{2}\end{matrix} ;$$

where, λ, α, and μ are all introduced variables having no physical meaning but being convenient to read. The simplified state variable xx is related to the input variable vₛₕ₍ₖ₎ obtained at the same time point. Therefore, a new state variable xₖ′ is introduced to avoid contradiction in the iterative calculation. The state variable xₖ′ is xₖ′=xₖ−λBvₛₕ₍ₖ₎, and the corresponding discrete voltage reconstruction function is converted into a discrete state space equation (also called an inverse black box model), which is xₖ′=αxₖ₋₁′+\tilde{B}vₛₕ₍ₖ₋₁₎; vₚₕ₍ₖ₎=Cxₖ′+Gvₛₕ₍ₖ₎; \tilde{B}=(αλ+μ)B; G=D+CλB, where G and \tilde{B} in the equation are both introduced variables, which have no physical meaning but are convenient to read. vₚₕ₍ₖ₎ is the primary-voltage high-frequency voltage component output by reconstruction. The input variable of the inverse black box model is a high-frequency and high-voltage component of the secondary signal, and the output variable of the inverse black box model is reconstructed to obtain the primary voltage.

In an embodiment of the present disclosure, the step of performing primary voltage reconstruction by applying the inverse electromagnetic duality model on the low-frequency voltage component, to obtain a primary-voltage low-frequency voltage component includes:
inputting the low-frequency voltage component into the inverse electromagnetic duality model, to perform reconstructing conversion on the low-frequency voltage component by a flux linkage conservation of the inverse electromagnetic duality model and Kirchhoff's current and voltage law, to obtain the primary-voltage low-frequency voltage component output by the inverse electromagnetic duality model.

Here, the Kirchhoff current and voltage law is:

$${v}_{p l} = n {v}_{m 1} + {R}_{s 1} {i}_{p l} ;$$

$${v}_{m 1} = {v}_{L s} + {v}_{m 2} ;$$

$${i}_{p l} = \frac{{i}_{m 1} + {i}_{Ls}}{n} ;$$

where vₚₗ is the primary-voltage low-frequency voltage component, n is a turn ratio of the inverse electromagnetic duality model, vₘ₁ is a voltage of a first excitation branch in the inverse electromagnetic duality model, vₘ₂ is a voltage of a second excitation branch in the inverse electromagnetic duality model, v_{Ls} is a voltage across a leakage inductance in the inverse electromagnetic duality model, Rₛ₁ is a resistance of a primary winding in the inverse electromagnetic duality model, iₚₗ is a primary current of the inverse electromagnetic duality model, iₘ₁ is a current flowing through the first excitation branch in the inverse electromagnetic duality model, and i_{Ls} is a current flowing across the leakage inductance in the inverse electromagnetic duality model.

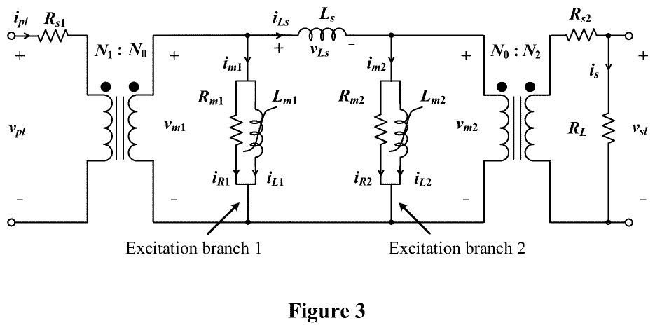

FIG. 3 is a schematic diagram of an inverse electromagnetic duality model in a method for reconstructing a primary voltage of a PT based on an inverse black box model and an inverse electromagnetic duality model according to an embodiment of the present disclosure.

It should be noted that the inverse electromagnetic duality model is mainly used to reconstruct the primary-voltage low-frequency voltage component, and is derived from a forward electromagnetic duality model of the PT. A low-frequency electromagnetic duality model of the PT is shown in FIG. 3, where Rₛ₁ and Rₛ₂ are a resistance of a primary winding of the inverse electromagnetic duality model and a resistance of a secondary winding of the inverse electromagnetic duality model, respectively; Lₛ is a leakage inductance of the inverse electromagnetic duality model. The leakage inductance and the resistances of the windings are constant, and two magnetizing inductances are Lₘ₁ and Lₘ₂ in FIG. 3 respectively, and are highly non-linear. Lₘ₁ and Lₘ₂ are related to magnetic permeabilities of different parts of an iron core. Shunt resistors Rₘ₁ and Rₘ₂ of the inverse electromagnetic duality model represent a magnetic core loss of the PT, which are much greater than a magnetized impedance. N₀, N₁, and N₂ are reference number of turns, number of PT primary winding turns, and number of PT secondary winding turns, respectively. vₚₗ, vₛₗ and iₚₗ are measured terminal voltages across the two windings and the primary current, respectively; R_{L} and iₛ are a load and a load current, respectively; i_{Ls} is a current flowing through the leakage inductance; vₘ₁, vₘ₂, iₘ₁, iₘ₂ are voltages and currents of excitation branches 1, 2, respectively; i_{L1}, i_{R1}, i_{L2}, i_{R2} are currents flowing through Lₘ₁, Rₘ₁, Lₘ₂, Rₘ₂, respectively; iₘ₁ and iₘ₂ are currents flowing through magnetizing branches 1 and 2, respectively. Here, it is assumed that N₀=N₂, and the turn ratio n=N₁/N₂.

As shown in FIG. 3, the inverse electromagnetic duality model is derived from a relationship between voltage and current in the forward electromagnetic duality model. The input variable of the inverse electromagnetic duality model is the low-frequency voltage component of the secondary signal, and the output variable of the inverse electromagnetic duality model is the primary-voltage low-frequency voltage component. The reconstruction of the primary-voltage low-frequency voltage component is specifically performed as follows.

The load current i_{L} is measured by an instrument and can also be calculated from the impedance of a load and a voltage across the load. Therefore, a calculation formula of the voltage across the magnetized branch 2 is vₘ₂=vₛₗ+iₛRₛ₂, and a magnetic chain is obtained by integrating the voltage. Therefore, a calculation formula of the flux linkage (λₘ₂) on the magnetized branch 2 is as follows:

$$λ ( {t}_{1} ) = {\int }_{0}^{{t}_{1}} v ( t ) d t + λ ( 0 ) ;$$

where t₁ is a duration of the integration, λ(0) is an initial value of λ, and a λ-i curve of a magnetized inductor can be obtained by a no-load test and a saturation test. Then a current flowing through a magnetized resistor is calculated by a formula, and a current flowing through the magnetized branch 2 is calculated by a formula. Similarly, i_{L1}, i_{R1}, and iₘ₁ can be calculated in the same way, where,

$${i}_{R 2} = \frac{{v}_{m 2}}{{R}_{m 2}} ; {i}_{m 2} = {i}_{L 2} + {i}_{R 2} .$$

In the inverse electromagnetic duality model, the leakage inductance is a constant. The current flowing through the leakage inductance is equal to iₘ₂. Therefore, the flux linkage and the voltage (λ_{Ls} and v_{Ls}) across the leakage inductance can be calculated by the following beam formula:

$${i}_{m 2} = {i}_{L 2} + {i}_{R 2} ,$$

$${i}_{L s} = {i}_{m 2} + {i}_{s} ,$$

$${λ}_{L s} = {i}_{L s} {L}_{s} ;$$

$${v}_{Ls} = {L}_{s} \frac{{di}_{Ls}}{dt} .$$

Then a summing calculation is used to calculate λₘ₁ and vₘ₁, respectively. The flux linkage conservation law in an inverse duality derivation model is: λₘ₁=λ_{Ls}+λₘ₂; vₘ₁=v_{Ls}+vₘ₂. Then the current flowing through the primary winding is obtained by iₚₗ=(iₘ₁+i_{Ls})/n, and then the primary voltage is calculated by vₚₗ=nvₘ₁+Rₛ₁iₚₗ, where λₘ₁ is the flux linkage of the magnetized branch 1 in the inverse electromagnetic duality model, λₘ₂ is the flux linkage of the magnetized branch 2 in the inverse electromagnetic duality model, and λ_{Ls} is the flux linkage of the leakage inductance in the inverse electromagnetic duality model. The resistance, inductance, and turn ratio of the PT are measured by testing or provided by equipment manufacturers. The voltage across the secondary winding is measured by a PT on site, and thus, it can be used to reconstruct the primary-voltage low-frequency voltage component of the PT. A summing calculation formula is obtained by using a trapezoidal integral and a central difference equation, for reconstructing the primary-voltage low-frequency voltage component based on the low-frequency voltage component of the discrete secondary signal.

$$Λ ( k ) = Λ ( k - 1 ) + \frac{[ V ( k - 1 ) + V ( k ) ] Δ t}{2} ;$$

$${V}_{L s} ( k ) = {L}_{s} \frac{{I}_{m 2} ( k ) - {I}_{m2} ( k - 1 )}{Δ t} ,$$

where Λ(k), V(k), V_{Ls}(k), and Iₘ₂(k) are discrete forms of λ(t), v(t), v_{Ls}(t), and iₘ₂(t), respectively, and k=1, 2, 3, . . . .

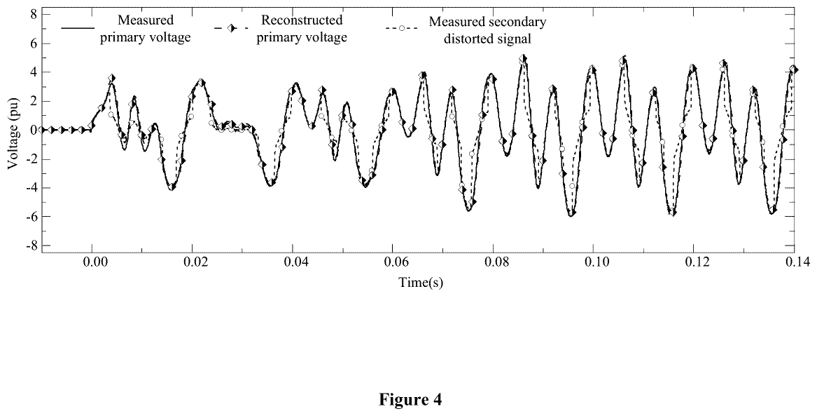

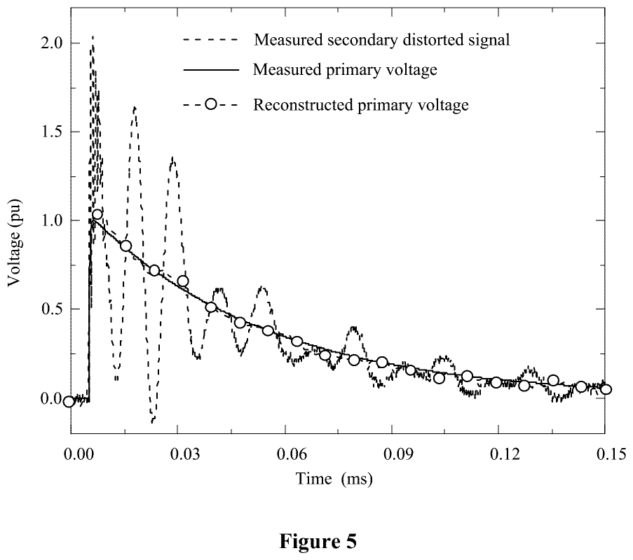

FIG. 4 is a comparison diagram of a distorted signal and a reconstructed signal by a method for reconstructing a primary voltage of a PT based on an inverse black box model and an inverse electromagnetic duality model according to an embodiment of the present disclosure. FIG. 5 is a comparison diagram of a distorted signal and a reconstructed signal by a method for reconstructing a primary voltage of a PT based on an inverse black box model and an inverse electromagnetic duality model according to another embodiment of the present disclosure.

In the embodiments of the present disclosure, the method for reconstructing a primary voltage of a PT based on an inverse black box model and an inverse electromagnetic duality model is used to perform reconstruction from distorted secondary voltage signals in a low-frequency transient ferroresonance overvoltage condition and a lightning impulse condition. Specifically, in the low-frequency transient ferroresonance overvoltage condition, FIG. 4 shows the comparison of an actual primary voltage, a distorted secondary signal, and a reconstructed primary voltage, which proves the high accuracy of a low-frequency primary voltage measured by the method for reconstructing a primary voltage of a PT based on an inverse black box model and an inverse electromagnetic duality model. The measurement accuracy meets cite requirements. As can be seen from FIG. 4, in ferroresonance, PT is saturated, and the secondary side signal is significantly distorted. However, the primary side voltage can be reconstructed by the method for reconstructing a primary voltage of a PT based on an inverse black box model and an inverse electromagnetic duality model, and the obtained result almost coincides with the actual primary side voltage. FIG. 5 shows a comparison of an actual primary voltage, a secondary distorted signal and a reconstructed primary voltage in the lightning impulse condition, which proves a high accuracy of the high-frequency primary voltage measured by the method for reconstructing a primary voltage of a PT based on an inverse black box model and an inverse electromagnetic duality model. The measurement accuracy meets the site requirements. As can be seen from FIG. 5, the secondary-side signal of the PT is distorted due to a frequency dependence of PT under lightning impulse, and an accurate primary-side lightning voltage can be reconstructed by the method for reconstructing a primary voltage of a PT based on an inverse black box model and an inverse electromagnetic duality model, which is almost coincident with the applied lightning impulse.

### Embodiment 2

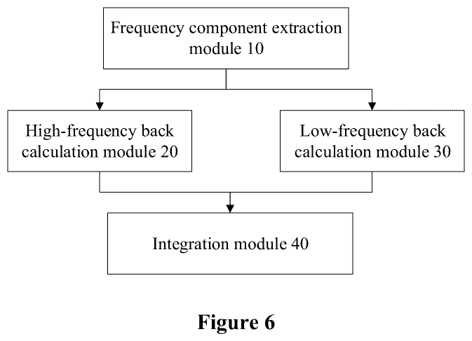

FIG. 6 is a block diagram of a device for reconstructing a primary voltage of a potential transformer (PT) based on an inverse black box model and an inverse electromagnetic duality model according to an embodiment of the present disclosure.

As shown in FIG. 6, a device for reconstructing a primary voltage of a PT based on an inverse black box model and an inverse electromagnetic duality model is provided in an embodiment of the present disclosure, including a frequency component extraction module 10, a high-frequency back calculation module 20, a low-frequency back calculation module 30, and an integration module 40.

The frequency component extraction module 10 is configured to collect a secondary voltage signal of a power system by the PT, and divide the secondary voltage signal into a low-frequency voltage component and a high-frequency voltage component.

The high-frequency back calculation module 20 is configured to perform primary voltage reconstruction by applying the inverse black box model on the high-frequency voltage component, to obtain a primary-voltage high-frequency voltage component.

The low-frequency back calculation module 30 is configured to perform primary voltage reconstruction by applying the inverse electromagnetic duality model on the low-frequency voltage component, to obtain a primary-voltage low-frequency voltage component.

The integration module 40 is configured to integrate the primary-voltage high-frequency voltage component and the primary-voltage low-frequency voltage component, to obtain the primary voltage of the power system.

In the embodiment of the present disclosure, the high-frequency back-calculation module 20 is further configured to: input the high-frequency voltage component into the inverse black box model, to perform reconstructing conversion on the high-frequency voltage component by a transfer function of the inverse black box model, to obtain the primary-voltage high-frequency voltage component output by the inverse black box model.

Here, the transfer function is vₚₕ(s)=Hₘ⁻¹(s) vₛₕ(s), where vₛₕ(s) is the input variable of the inverse black box model, vₚₕ(s) is the output variable of the inverse black box model, and Hₘ⁻¹(s) is the transfer function of the inverse black box model.

The high-frequency back calculation module 20 includes a conversion sub-module and a calculation sub-module.

The conversion sub-module is configured to perform fitting transformation on the transfer function, to obtain a state equation of the transfer function; and convert the state equation by introducing a variable x and a center difference method, to obtain a discrete voltage reconstruction function.

The calculation sub-module is configured to perform iterative calculating on the discrete voltage reconstruction function, to obtain a reconstructed primary-voltage high-frequency voltage component.

Here, the discrete voltage reconstruction function is:

$$\begin{matrix}\frac{{x}_{k} - {x}_{k - 1}}{Δ t} = A \frac{{x}_{k} + {x}_{k - 1}}{2} + B \frac{{v}_{s h ( k )} + {v}_{s h ( k - 1 )}}{2} \\ {v}_{p h ( k )} = C {x}_{k} + D {v}_{s h ( k )}\end{matrix}$$

Here, x is a symbol of the introduced variable, k and k−1 are time points of the k-th and (k−1)-th of high-frequency voltage components, A is an N×N diagonal matrix of an extreme point of the transfer function, B is an N×1 array, Δt is a time interval between time points corresponding to the k-th high-frequency voltage component and the (k−1)-th high-frequency voltage component, C is an 1×N array of a zero point of the transfer function, and D is a constant term.

In an embodiment of the present disclosure, the low-frequency back calculation module 30 is further configured to: input the low-frequency voltage component into the inverse electromagnetic duality model, to perform reconstructing conversion on the low-frequency voltage component by a flux linkage conservation of the inverse electromagnetic duality model and a Kirchhoff's current and voltage law, to obtain the primary-voltage low-frequency voltage component output by the inverse electromagnetic duality model.

Here, the flux conservation and the Kirchhoff's current and voltage law are:

$${v}_{p l} = n {v}_{m 1} + {R}_{s 1} {i}_{p l} ;$$

$${v}_{m 1} = {v}_{L s} + {v}_{m 2} ;$$

$${i}_{p l} = \frac{{i}_{m 1} + {i}_{Ls}}{n} ;$$

Here, vₚₗ is the primary-voltage low-frequency voltage component, n is a turn ratio of the inverse electromagnetic duality model, vₘ₁ is a voltage of a first excitation branch in the inverse electromagnetic duality model, vₘ₂ is a voltage of a second excitation branch in the inverse electromagnetic duality model, v_{Ls} is a voltage across a leakage inductance in the inverse electromagnetic duality model, Rₛ₁ is a resistance of a primary winding in the inverse electromagnetic duality model, iₚₗ is a primary current of the inverse electromagnetic duality model, iₘ₁ is a current flowing through the first excitation branch in the inverse electromagnetic duality model, and i_{Ls} is a current flowing across the leakage inductance in the inverse electromagnetic duality model.

It should be noted that the modules in the device according to Embodiment 2 correspond to the steps in the method according to Embodiment 1. The steps in the method according to Embodiment 1 have been described in detail, and thus the modules in the device in Embodiment 2 will not be described in detail.

### Embodiment 3

An apparatus for reconstructing a primary voltage of a potential transformer (PT) based on an inverse black box model and an inverse electromagnetic duality model is provided in the embodiments of the present disclosure, including a processor and a memory,
where the memory is configured to store program codes, and transmit the program codes to the processor; and
the processor is configured to execute instructions in the program codes to implement the above method for reconstructing a primary voltage of a potential transformer (PT) based on an inverse black box model and an inverse electromagnetic duality model.

It should be noted that the processor is configured to execute the steps in the above-described method for reconstructing a primary voltage of a potential transformer (PT) based on an inverse black box model and an inverse electromagnetic duality model according to the instructions in the program codes. Alternatively, the processor performs the functions of the modules/units in the above-described system/apparatus embodiments when executing a computer program.

Exemplarily, the computer program may be divided into one or more modules/units that are stored in the memory and executed by the processor to complete the present disclosure. The one or more modules/units may be a series of computer program instruction segments capable of performing a particular function, the computer program instruction segments describing the execution of the computer program in a terminal device.

The terminal device may be a computing device such as a desktop computer, a notebook, a palmtop computer, or a cloud server. The terminal device may include, but is not limited to, a processor, and a memory. It will be appreciated by those skilled in the art that this does not constitute a limitation on the terminal device, and the terminal device may include more or less components than illustrated, or may combine certain components, or may include different components, e.g., the terminal device may also include an input/output device, a network access device, a bus, etc.

The processor may be a Central Processing Unit (CPU) or other general purpose processor, Digital Signal Processor (DSP), Application Specific Integrated Circuit (ASIC), Field-Programmable Gate Array (FPGA) or other programmable logic device, discrete gate or transistor logic device, discrete hardware component, etc. The general purpose processor may be a microprocessor or the processor may be any conventional processor or the like.

The memory may be an internal storage unit of the terminal device, such as a hard disk or memory of the terminal device. The memory may also be an external storage device of the terminal device, such as a plug-in hard disk, a Smart Media Card (SMC), a Secure Digital (SD) card, a Flash Card, or the like provided on the terminal device. Further, the memory may also include both an internal storage unit of the terminal device and an external storage device. The memory is used to store computer programs as well as other programs and data required by the terminal device. The memory may also be used to temporarily store data that has been or is to be output.

It will be apparent to those skilled in the art that, for the convenience and brevity of the description, reference may be made to the corresponding processes in the foregoing method embodiments for specific working procedures of the above-described systems, apparatuses and units, and details will not be described herein.

In the several embodiments provided herein, it is to be understood that the disclosed systems, apparatus, and methods may be implemented in other ways. For example, the device embodiments described above are merely illustrative, for example, the division of the units is merely a logical functional division, and there may be additional division in practice, for example, a plurality of units or components may be combined or integrated into another system, or some features may be ignored or not performed. On the other hand, the coupling or direct coupling or communication connection between each other shown or discussed may be through some interface, indirect coupling or communication connection of a device or unit, and may be in electrical, mechanical or other form.

The units illustrated as separate parts may or may not be physically separate, and the units shown as parts may or may not be physical units. They may be located at one location, or may be distributed across multiple network units. Some or all of the units may be selected according to actual needs to achieve the objectives of the embodiments.

In addition, the functional units in the various embodiments of the present disclosure may be integrated in one processing unit, may be separate physical units, or may be integrated in two or more units. The integrated units described above may be implemented in the form of hardware or in the form of software functional units.

The integrated unit, if implemented as a software functional unit and sold or used as a stand-alone product, may be stored in a computer-readable storage medium. On the basis of such an understanding, the technical solution of the present disclosure may essentially be embodied in the form of a software product, which is stored in a storage medium and includes instructions for causing a computer device (which may be a personal computer, a server, a network device, or the like) to perform all or part of the steps of the methods described in the various embodiments of the present disclosure. The storage medium includes a USB flash drive, a removable hard disk, a read-only memory (ROM, Read-Only Memory), a random access memory (RAM, Random Access Memory), a magnetic disk, or an optical disk.

As described above, the above embodiments are merely illustrative of the technical solution of the present disclosure, and are not limited thereto. While the present disclosure has been described in detail with reference to the foregoing embodiments, it will be understood by those of ordinary skill in the art that modifications may still be made to the technical solutions described in the foregoing embodiments, or equivalents may be made to some of the technical features thereof. These modifications or substitutions do not depart from the spirit and scope of the embodiments of the present disclosure.

1. A method for reconstructing a primary voltage of a potential transformer (PT) based on an inverse black box model and an inverse electromagnetic duality model, comprising:
collecting a secondary voltage signal of a power system by the PT, and dividing the secondary voltage signal into a low-frequency voltage component and a high-frequency voltage component;
performing primary voltage reconstruction by applying the inverse black box model on the high-frequency voltage component, to obtain a primary-voltage high-frequency voltage component;
performing primary voltage reconstruction by applying the inverse electromagnetic duality model on the low-frequency voltage component, to obtain a primary-voltage low-frequency voltage component; and
integrating the primary-voltage high-frequency voltage component and the primary-voltage low-frequency voltage component, to obtain the primary voltage of the power system.

2. The method according to claim 1, wherein the dividing the secondary voltage signal into a low-frequency voltage component and a high-frequency voltage component comprises:
performing Fourier transform processing on the secondary voltage signal, to obtain a frequency domain of the secondary voltage signal;
dividing the frequency domain of the secondary voltage signal into a low-frequency domain of the secondary voltage signal and a high-frequency domain of the secondary voltage signal according to whether respective frequencies in the frequency domain of the secondary voltage signal are greater than a transition frequency; and
performing inverse Fourier transform on the low-frequency domain of the secondary voltage signal and the high-frequency domain of the secondary voltage signal, respectively, to obtain the low-frequency voltage component and the high-frequency voltage component.

3. The method according to claim 1, wherein the performing primary voltage reconstruction by applying the inverse black box model on the high-frequency voltage component, to obtain a primary-voltage high-frequency voltage component comprises:
inputting the high-frequency voltage component into the inverse black box model, to perform reconstructing conversion on the high-frequency voltage component by a transfer function of the inverse black box model, to obtain the primary-voltage high-frequency voltage component output by the inverse black box model,
wherein the transfer function is vₚₕ(s)=Hₘ⁻¹(s) vₛₕ(s), where vₛₕ(s) is an input variable of the inverse black box model, vₚₕ(s) is an output variable of the inverse black box model, and Hₘ⁻¹(s) is the transfer function of the inverse black box model.

4. The method according to claim 3, wherein the performing reconstructing conversion on the high-frequency voltage component by a transfer function of the inverse black box model comprises:
performing fitting transformation on the transfer function, to obtain a state equation of the transfer function;
converting the state equation by introducing a variable x and a center difference method, to obtain a discrete voltage reconstruction function; and
performing iterative calculating on the discrete voltage reconstruction function, to obtain a reconstructed primary-voltage high-frequency voltage component,
wherein the discrete voltage reconstruction function is:
$$\frac{{x}_{k} - {x}_{k - 1}}{Δ t} = A \frac{{x}_{k} + {x}_{k - 1}}{2} + B \frac{{v}_{s h ( k )} + {v}_{s h ( k - 1 )}}{2}$$
$${v}_{p h ( k )} = C {x}_{k} + D {v}_{s h ( k )}$$
where x is a symbol of the introduced variable, k and k−1 are time points of the k-th and (k−1)-th of high-frequency voltage components, A is an N×N diagonal matrix of an extreme point of the transfer function, B is an N×1 array, Δt is a time interval between time points corresponding to the k-th high-frequency voltage component and the (k−1)-th high-frequency voltage component, C is an 1×N array of a zero point of the transfer function, and D is a constant term.

5. The method according to claim 1, wherein the performing primary voltage reconstruction by applying the inverse electromagnetic duality model on the low-frequency voltage component, to obtain a primary-voltage low-frequency voltage component comprises:
inputting the low-frequency voltage component into the inverse electromagnetic duality model, to perform reconstructing conversion on the low-frequency voltage component by a flux linkage conservation of the inverse electromagnetic duality model and a Kirchhoff's current and voltage law, to obtain the primary-voltage low-frequency voltage component output by the inverse electromagnetic duality model,
wherein the Kirchhoff' current and voltage law is:
$${v}_{p l} = n {v}_{m 1} + {R}_{s 1} {i}_{p l} ;$$
$${v}_{m 1} = {v}_{L s} + {v}_{m 2} ;$$
$${i}_{p l} = \frac{{i}_{m 1} + {i}_{Ls}}{n} ;$$
where vₚₗ is the primary-voltage low-frequency voltage component, n is a turn ratio of the inverse electromagnetic duality model, vₘ₁ is a voltage of a first excitation branch in the inverse electromagnetic duality model, vₘ₂ is a voltage of a second excitation branch in the inverse electromagnetic duality model, v_{Ls} is a voltage across a leakage inductance in the inverse electromagnetic duality model, Rₛ₁ is a resistance of a primary winding in the inverse electromagnetic duality model, iₚₗ is a primary current of the inverse electromagnetic duality model, iₘ₁ is a current flowing through the first excitation branch in the inverse electromagnetic duality model, and i_{Ls} is a current flowing across the leakage inductance in the inverse electromagnetic duality model.

6. The method according to claim 1, wherein the integrating the primary-voltage high-frequency voltage component and the primary-voltage low-frequency voltage component, to obtain the primary voltage of the power system comprises: adding the primary-voltage high-frequency voltage component and the primary-voltage low-frequency voltage component, to obtain the primary voltage of the power system.

7. A device for reconstructing a primary voltage of a potential transformer (PT) based on an inverse black box model and an inverse electromagnetic duality model, comprising: a frequency component extraction module, a high-frequency back calculation module, a low-frequency back calculation module, and an integration module,
wherein the frequency component extraction module is configured to collect a secondary voltage signal of a power system by the PT, and dividing the secondary voltage signal into a low-frequency voltage component and a high-frequency voltage component;
the high-frequency back calculation module is configured to perform primary voltage reconstruction by applying the inverse black box model on the high-frequency voltage component, to obtain a primary-voltage high-frequency voltage component;
the low-frequency back calculation module is configured to perform primary voltage reconstruction by applying the inverse electromagnetic duality model on the low-frequency voltage component, to obtain a primary-voltage low-frequency voltage component; and
the integration module is configured to integrate the primary-voltage high-frequency voltage component and the primary-voltage low-frequency voltage component, to obtain the primary voltage of the power system.

8. The device according to claim 7, wherein the high-frequency back calculation module is further configured to: input the high-frequency voltage component into the inverse black box model, to perform reconstructing conversion on the high-frequency voltage component by a transfer function of the inverse black box model, to obtain the primary-voltage high-frequency voltage component output by the inverse black box model,
wherein the transfer function is vₚₕ(s)=Hₘ⁻¹(s) vₛₕ(s), where vₛₕ(s) is an input variable of the inverse black box model, vₚₕ(s) is an output variable of the inverse black box model, and Hₘ⁻¹(s) is the transfer function of the inverse black box model; and
wherein the high-frequency back calculation module comprises a conversion sub-module and a calculation sub-module,
where the conversion sub-module is configured to perform fitting transformation on the transfer function, to obtain a state equation of the transfer function; and convert the state equation by introducing a variable x and a center difference method, to obtain a discrete voltage reconstruction function, and
the calculation sub-module is configured to perform iterative calculating on the discrete voltage reconstruction function, to obtain a reconstructed primary-voltage high-frequency voltage component,
wherein the discrete voltage reconstruction function is:
$$\frac{{x}_{k} - {x}_{k - 1}}{Δ t} = A \frac{{x}_{k} + {x}_{k - 1}}{2} + B \frac{{v}_{s h ( k )} + {v}_{s h ( k - 1 )}}{2}$$
$${v}_{p h ( k )} = C {x}_{k} + D {v}_{s h ( k )}$$
where x is a symbol of the introduced variable, k and k−1 are time points of the k-th and (k−1)-th of high-frequency voltage components, A is an N×N diagonal matrix of an extreme point of the transfer function, B is an N×1 array, Δt is a time interval between time points corresponding to the k-th high-frequency voltage component and the (k−1)-th high-frequency voltage component, C is an 1×N array of a zero point of the transfer function, and D is a constant term.

9. The device according to claim 7, wherein the low-frequency back calculation module is further configured to: input the low-frequency voltage component into the inverse electromagnetic duality model, to perform reconstructing conversion on the low-frequency voltage component by a flux linkage conservation of the inverse electromagnetic duality model and the Kirchhoff's current and voltage law, to obtain the primary-voltage low-frequency voltage component output by the inverse electromagnetic duality model,
wherein the Kirchhoff's current and voltage law is:
$${v}_{p l} = n {v}_{m 1} + {R}_{s 1} {i}_{p l} ;$$
$${v}_{m 1} = {v}_{L s} + {v}_{m 2} ;$$
$${i}_{p l} = \frac{{i}_{m 1} + {i}_{Ls}}{n} ;$$
where vₚₗ is the primary-voltage low-frequency voltage component, n is a turn ratio of the inverse electromagnetic duality model, vₘ₁ is a voltage of a first excitation branch in the inverse electromagnetic duality model, vₘ₂ is a voltage of a second excitation branch in the inverse electromagnetic duality model, v_{Ls} is a voltage across a leakage inductance in the inverse electromagnetic duality model, Rₛ₁ is a resistance of a primary winding in the inverse electromagnetic duality model, iₚₗ is a primary current of the inverse electromagnetic duality model, iₘ₁ is a current flowing through the first excitation branch in the inverse electromagnetic duality model, and i_{Ls} is a current flowing across the leakage inductance in the inverse electromagnetic duality model.

10. An apparatus for reconstructing a primary voltage of a potential transformer (PT) based on an inverse black box model and an inverse electromagnetic duality model, comprising a processor and a memory;
wherein the memory is configured to store program codes, and transmit the program codes to the processor, and
the processor is configured to execute instructions in the program codes to implement the method for reconstructing a primary voltage of a PT based on an inverse black box model and an inverse electromagnetic duality model according to claim 1.
